(19) United States
(12) Patent Application Publication
(10) Pub. No.: US 2025/0081786 A1
(43) Pub. Date: Mar. 6, 2025

(54) DISPLAY PANEL AND ELECTRONIC DEVICE

(71) Applicant: SHENZHEN CHINA STAR OPTOELECTRONICS SEMICONDUCTOR DISPLAY TECHNOLOGY CO., LTD., Shenzhen (CN)

(72) Inventor: Kuo GAO, Shenzhen (CN)

(21) Appl. No.: 17/769,744

(22) PCT Filed: Mar. 28, 2022
(86) PCT No.: PCT/CN2022/083337

§ 371 Date: Nov. 22, 2024

(30) Foreign Application Priority Data
Mar. 17, 2022 (CN) 202210264826.3

(51) Int. Cl. H10K 59/35; H10K 59/80

(52) U.S. Cl. CPC H10K 59/353; H10K 59/352; H10K 59/873

(57) ABSTRACT

The present application provides a display panel and an electronic device. The display panel includes first pixel unit groups and second pixel unit groups. Each first pixel unit group and each second pixel unit group both include two pixels which are center-symmetrical to each other. Each pixel includes at least three light-emitting units of different colors arranged at intervals. In any two adjacent pixels, one of the light-emitting units of one pixel has the same color as the adjacent light-emitting unit of the other pixel, so as to alleviate a problem of color mixing between pixels in conventional organic light emitting diode (OLED) devices.

### FIELD OF DISCLOSURE

The present application relates to a field of display technology and in particular, to a display panel and an electronic device.

### BACKGROUND OF RELATED ARTS

Organic light emitting diode (OLED) devices have gradually replaced liquid crystal displays and become high-end displays due to their advantages such as ultra-high contrast ratios, wide color gamut, fast response time, and active light emission. Generally, a light emitting layer of the OLED device can be prepared by ink jet printing (IJP) or evaporation deposition. Compared with conventional evaporation deposition processes, ink jet printing has advantages such as a wide color gamut, high material utilization, and a high resolution. However, the inkjet printing bas a risk of color mixing between pixels.

### SUMMARY OF INVENTION

### Technical Problem

The present application provides a display panel and an electronic device to alleviate technical problems of color mixing between pixels in conventional OLED devices.

### Solution to Problem

### Technical Solutions

Accordingly, the present application provides technical solutions as follows.

The present application provides a display panel, including:

a substrate;

a plurality of first pixel unit groups and a plurality of second pixel unit groups which are alternately arranged on the substrate along a first direction, wherein each of the first pixel unit groups and each of the second pixel unit groups both include two pixels which are center-symmetrical to each other;

wherein each of the pixels includes at least three light-emitting units of different colors arranged at intervals;

in any two adjacent pixels, one of the light-emitting units of one of the two pixels has a same color as the adjacent light-emitting unit of the other pixel.

In the display panel according to one embodiment of the present application, along the first direction, each first pixel unit group and the adjacent second pixel unit group are axially symmetrical.

In the display panel according to one embodiment of the present application, along a second direction, the first pixel unit groups are arranged in an array pattern, and the second pixel unit groups are also arranged in an array pattern; and the first pixel unit groups and the second pixel unit groups are arranged in different rows.

In the display panel according to one embodiment of the present application, along the second direction, two adjacent pixels are center-symmetrical.

In the display panel according to one embodiment of the present application, along a second direction, the first pixel unit groups and the second pixel unit groups are alternately arranged.

In the display panel according to one embodiment of the present application, along the second direction, each first pixel unit group and the adjacent second pixel unit group are axially symmetrical.

In the display panel according to one embodiment of the present application, along the first direction, each first pixel unit group and the adjacent second pixel unit group are center-symmetrical.

In the display panel according to one embodiment of the present application, the first pixel unit groups and the second pixel unit groups are all rhombus-shaped; the three light-emitting units of different colors in each pixel are all triangle-shaped; each of the light-emitting units includes two short sides and one long side; in each light-emitting unit, a length of the long side is greater than a length of each short side; in each of the pixels, the two short sides of each light-emitting unit form a vertex, the vertices are close to each other, and extension lines of the long sides of the light-emitting units form an isosceles triangle.

In the display panel according to one embodiment of the present application, the first pixel unit groups and the second pixel unit groups are all square-shaped; the light-emitting units of three different colors in each of the pixels are all triangle-shaped; each of the light-emitting units includes two short sides and one long side; in each light-emitting unit, a length of the long side is greater than a length of each short side; and in each of the pixels, the two short sides of each light-emitting unit form a vertex, the vertices are close to each other, and extension lines of the long sides of the light-emitting units form a right triangle.

In the display panel according to one embodiment of the present application, the three light-emitting units of different colors are a first-color light-emitting unit, a second-color light-emitting unit, and a third-color light-emitting unit; each first-color light-emitting unit is a blue light-emitting unit; and within the same pixel, an area of the first-color light-emitting unit is larger than an area of the second-color light-emitting unit and is larger than an area of the third-color light-emitting unit.

In the display panel according to one embodiment of the present application, the display panel further including:

a plurality of first electrodes arranged in an array on the substrate;

a pixel definition layer, wherein the pixel definition layer covers the substrate and the first electrodes and includes a plurality of pixel openings corresponding to the plurality of first electrodes, each pixel opening exposes the corresponding first electrode;

each of the light-emitting units is disposed in one of the pixel openings;

a plurality of barrier layers disposed on one side of the pixel definition layer away from the substrate, wherein each barrier layer is disposed between two adjacent ones of the light-emitting units of different colors.

In the display panel according to one embodiment of the present application, a material of the barrier layer is a hydrophobic material.

The present application further provides an electronic device which includes the display panel of one of the above embodiments.

### Advantages of Invention

### Beneficial Effect

In the display panel and the electronic device of the present application, the display panel includes a substrate and a plurality of first pixel unit groups and a plurality of second pixel unit groups alternately arranged on the substrate along a first direction. The first pixel unit groups and each of the second pixel unit groups both include two pixels which are center-symmetrical to each other. Each of the pixels includes at least three light-emitting units of different colors arranged at intervals. In any two adjacent pixels, one of the light-emitting units of one of the two pixels has the same color as the adjacent light-emitting unit of the other pixel. In the present application, the two adjacent light-emitting units between two adjacent pixels have the same color, so that when the light-emitting unit is printed by inkjet printing, color mixing between the pixels can be prevented, thereby solving a color mixing problem between pixels in conventional OLED devices.

### BRIEF DESCRIPTION OF DRAWINGS

### Description of Attached Drawings

In order to more clearly illustrate the embodiments of the present application, figures which will be described in the embodiments are briefly introduced hereinafter. It is obvious that the drawings are merely for the purposes of illustrating some embodiments of the present application, and a person having ordinary skill in this field can obtain other figures according to these figures without inventive work.

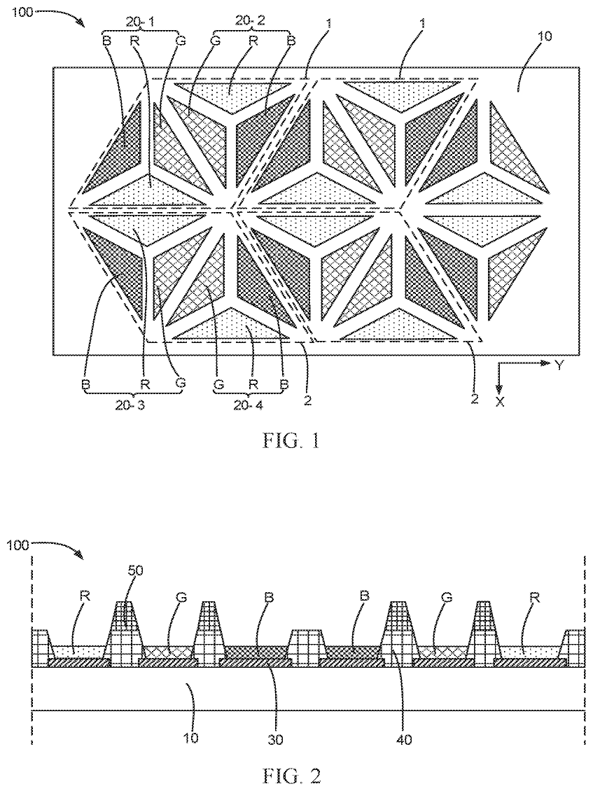

FIG. 1 is a schematic top view of a display panel according to one embodiment of the present application.

FIG. 2 is a schematic cross-sectional view of the display panel according to one embodiment of the present application.

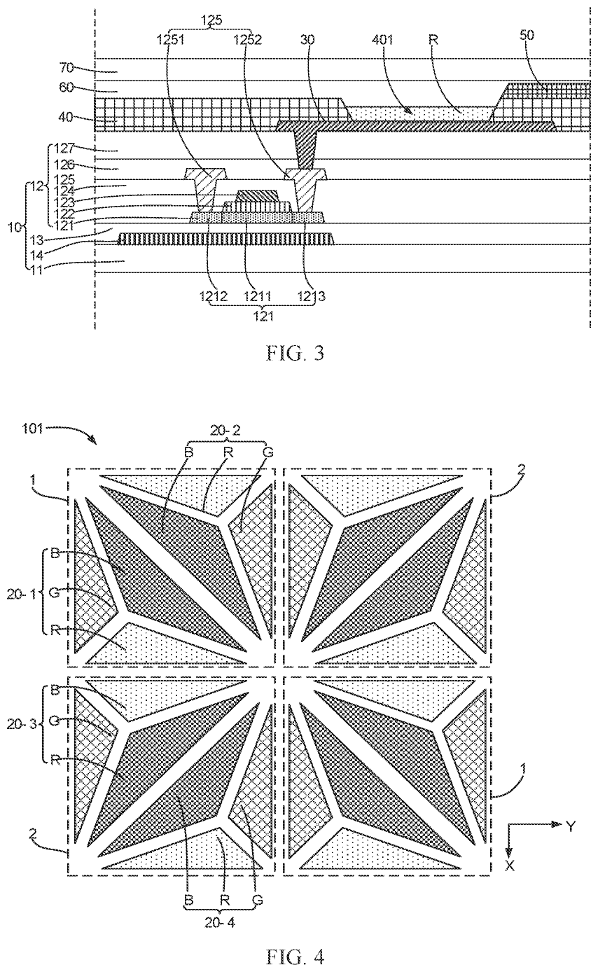

FIG. 3 is a schematic view of a partial structure of the display panel according to one embodiment of the present application.

FIG. 4 is a top view of the display panel according to another embodiment of the present application.

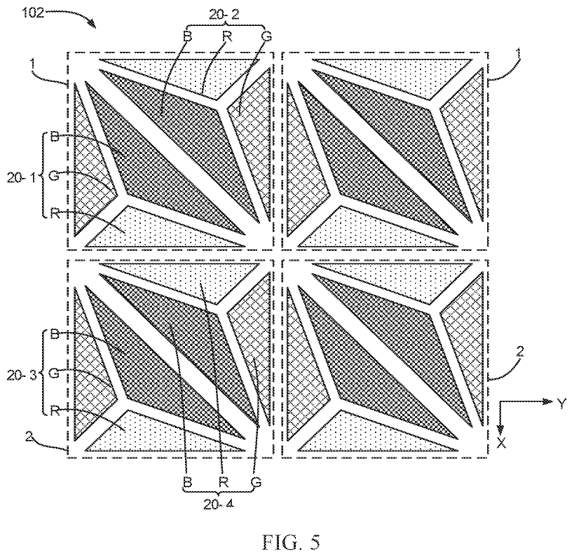

FIG. 5 is a top view of the display panel according to still another embodiment of the present application.

### EMBODIMENTS OF INVENTION

### DETAILED DESCRIPTION OF PREFERRED EMBODIMENTS

The present application is described below with reference to accompanying drawings and in conjunction with embodiments. Directional terms mentioned in the present application, such as “upper”, “lower”, “front”, “rear”, “left”, “right”, “inner”, “outer”, and “lateral”, are only illustrative with reference to the accompanying drawings. Therefore, the directional terms are used to describe and understand the present application, rather than to limit the present application. In the drawings, structurally similar elements are denoted by the same reference numerals. In the drawings, thicknesses of some layers and regions are exaggerated for ease of understanding and description. That is, the size and thickness of each component shown in the drawings are not in scale, and the present application is not limited in this regard.

Please refer to FIGS. 1 to 3 in combination. FIG. 1 is a schematic top view of a display panel according to one embodiment of the present application, FIG. 2 is a schematic cross-sectional view of the display panel according to one embodiment of the present application, and FIG. 3 is a schematic view of a partial structure of the display panel according to one embodiment of the present application. The display panel 100 includes a substrate 10 and a plurality of pixels (e.g., a first pixel 20-1, a second pixel 20-2, a third pixel 20-3, and a fourth pixel 20-4 as shown in FIG. 1) arranged on the substrate 10. Each of the pixels includes at least three light-emitting units (the light-emitting units R, G, B as shown in FIG. 1) of different colors arranged at intervals. In any two adjacent pixels, one of the light-emitting units of one of the pixels has the same color as the adjacent light-emitting unit of the other pixel.

Specifically, the display panel 100 further includes a plurality of first electrodes 30 arranged on the substrate 10 in an array pattern and a pixel definition layer 40. The pixel definition layer 40 covers the substrate 10 and the first electrodes 30. A plurality of pixel openings 401 are defined at positions corresponding to the first electrodes 30. Each pixel opening 401 exposes the corresponding first electrode 30. Each of the light-emitting units is disposed in one of the pixel openings 401.

Specifically, the substrate 10 includes a substrate 11 and a driving circuit layer 12 disposed on the substrate 11. Optionally, a buffer layer 13 can be further disposed between the substrate 11 and the driving circuit layer 12. A material of the buffer layer 13 can include silicon oxide (SiOx), silicon nitride (SiNx), silicon oxynitride (SiON), and other inorganic materials. The buffer layer 13 can further prevent undesired impurities or contaminants (e.g., moisture, oxygen, etc.) from diffusing from the substrate 11 to devices that can be damaged by these impurities or contaminants, while also providing a flat top surface.

Optionally, the substrate 11 can be a rigid substrate or a flexible substrate. In the case where the substrate 11 is a rigid substrate, the substrate 11 can include a rigid substrate such as a glass substrate 10. In the case where the substrate 11 is a flexible substrate, the substrate 11 can include a flexible substrate such as a polyimide (PI) film and an ultra-thin glass film. A flexible display panel can be fabricated by using a flexible substrate as the substrate 11 to achieve special properties such as bending and rolling of the display panel 100.

The driving circuit layer 12 includes an active layer 121, a gate insulating layer 122, a gate 123, an interlayer insulating layer 124, a source-drain layer 125, a passivation layer 126, and a planarization layer 127. The active layer 121 includes a channel region 1211 and a source region 1212 and a drain region 1213 located at two sides of the channel region 1211. The gate insulating layer 122 covers the active layer 121 and is disposed corresponding to the channel region 1211.

The gate 123 is disposed on the gate insulating layer 122, and the gate 123 is disposed corresponding to the channel region 1211.

Optionally, the substrate 10 further includes a light shielding layer 14. The light shielding layer 14 is disposed on the substrate 11, and the buffer layer 13 covers the light shielding layer 14 and the substrate 11. The light shielding layer 14 is disposed corresponding to the active layer 121, so that an orthographic projection of the active layer 121 projected on the substrate 11 falls within an orthographic projection of the light shielding layer 14 projected on the substrate 11. That is to say, the light shielding layer 14 can completely shield the active layer 121 to prevent light from irradiating the active layer 121

The interlayer insulating layer 124 covers the gate 123 and the buffer layer 13, the source-drain layer 125 is disposed on the interlayer insulating layer 124, and the source-drain layer 125 is patterned to form a source 1251, a drain 1252, etc. The source 1251 is connected to the source region 1212 through a via hole of the interlayer insulating layer 124, and the drain 1252 is connected to the drain region 1213 through another via hole of the interlayer insulating layer 124.

The passivation layer 126 covers the source-drain layer 125 and the interlayer insulating layer 124. The planarization layer 127 covers the passivation layer 126. The planarization layer 127 can provide a flat film surface for the substrate 10.

It should be noted that the driving circuit layer 12 of the present application is not limited to the structure shown in the present embodiment. The driving circuit layer 12 of the present application can also include more or less film layers, and a positional relationship of the film layers is not limited to the positional relationship illustrated in the present embodiment. For example, the gate 123 can also be located below the active layer 121 to form a bottom gate structure.

The first electrodes 30 are arranged on the planarization layer 127. Each of the first electrodes 30 is connected to the source 1251 or the drain 1252 through a via hole defined in the planarization layer 127 and the passivation layer 126. In the present application, the first electrode 30 is connected to the drain 1252 as an example for illustration.

Optionally, the first electrode 30 can be a transparent electrode or a reflective electrode. If the first electrode 30 is a transparent electrode, the first electrode 30 can be made of, for example, indium tin oxide (ITO), indium zinc oxide (IZO), ZnO, or In₂O₃. If the first electrode 30 is a reflective electrode, the first electrode 30 can include, for example, a reflective layer made of Ag, Mg, Al. Pt, Pd, Au, Ni, Nd, Ir, Cr, or a combination thereof, and include a layer made of ITO, IZO, ZnO, or In₂O₃. However, the first electrode 30 is not limited to the above mentioned, and the first electrode 30 can be made of various materials, and can also be formed to be a single-layer or multi-layer structure.

The pixel definition layer 40 covers the first electrode 30 and the planarization layer 127. The pixel definition layer 40 is patterned to form pixel openings 401. Each of the pixel openings 401 is arranged corresponding to one of the first electrodes 30, and exposes a portion of the corresponding first electrode 30 to define an area of the light-emitting unit. The light-emitting unit is disposed in the pixel opening 401 and covers the first electrode 30 in the pixel opening 401.

The light-emitting units of different colors are formed by printing light-emitting materials of different colors in the pixel openings 401. Specifically, the light-emitting materials of different colors are respectively melted in different organic solutions to form inks of different colors. Then, the inks of different colors are respectively printed in different pixel openings 401 by techniques such as inkjet printing to form the light-emitting units of different colors. Light-emitting materials of different colors emit light of different colors. For example, the red light-emitting material emits red light, the green light-emitting material emits green light, and blue light-emitting material emits blue light, so that the formed light-emitting units of different colors emit light of different colors.

Specifically, the three light-emitting units of different colors are a first-color light-emitting unit B, a second-color light-emitting unit R, and a third-color light-emitting unit G. The first-color light-emitting unit B is a blue light-emitting unit which emits blue light. The second-color light-emitting unit R is a red light-emitting unit which emits red light The third-color light-emitting unit G is a green light-emitting unit which emits green light Surface shapes of the first-color light-emitting unit B, the second-color light-emitting unit R, and the third-color light-emitting unit G are all triangles; however, the present application is not limited in this regard, and the surface shapes of the light-emitting units can also be other regular or irregular shapes.

Each of the pixels includes at least three light-emitting units of different colors, that is, each of the pixels includes the first-color light-emitting unit B, the second-color light-emitting unit R, and the third-color light-emitting unit G, so that each of the pixels can display various colors, and accordingly the display panel 100 can realize color display.

It can be understood that, in order to make the light-emitting unit emit light, the display panel 100 further includes a plurality of second electrodes 60 disposed on the light-emitting units and the pixel definition layer 40. The light-emitting units emit light under cooperation between the first electrodes 30 and the second electrodes 60. The light-emitting units of different colors emit light of different colors, thereby realizing full-color display operations of the display panel 100. The first electrode 30 of the present application is an anode, and the second electrode 60 is a cathode; however, the present application is not limited to in this regard, and the first electrode 30 in the present application can also be a cathode, and accordingly, the second electrode 60 is an anode.

Optionally, in order to improve light transmittance, the second electrode 60 is made of a transparent conductive material. For example, the second electrode 60 can be made of a transparent conductive oxide (TCO) such as ITO, IZO, ZnO, or In₂O₃.

Alternatively, the display panel 100 can further include a hole injection layer (HIL) and a hole transport layer (HTL) disposed between the light-emitting units and the first electrodes 30, and include an electron injection layer (EIL) and an electron transport layer (ETL) between the light-emitting units and the second electrodes 60. The hole injection layer receives holes transported by the first electrode 30, and the holes are transported to the light-emitting units via the hole transport layer. The electron injection layer receives electrons transported by the second electrodes 60. The electrons are transported to the light-emitting units through the electron transport layer. After the holes are combined with the electrons at positions of the light-emitting units, excitons are generated, and the excitons transiting from an excited state to a ground state release energy and emit light.

Furthermore, in order to protect the light-emitting units and prevent the light-emitting units from being damaged due to moisture and oxygen intrusion, the display panel 100 further includes an encapsulation layer 70 disposed on the second electrodes 60. Optionally, the encapsulation layer 70 can be encapsulated by a thin film. For example, the encapsulation layer 70 can be a stacked structure of three thin films, which is formed by successively stacking a first inorganic encapsulation layer, an organic encapsulation layer, and a second inorganic encapsulation layer, or the encapsulation layer 70 can be a stacked structure of more than three layers.

In addition, since the two adjacent light-emitting units between each two adjacent pixels have the same color, color mixing between the adjacent pixels can be prevented, and the display quality can be improved. A detailed description is provided below to explain how to make the adjacent light-emitting units between the adjacent pixels have the same color.

Optionally, the display panel 100 includes the first pixel unit groups 1 and the second pixel unit groups 2 sequentially arranged along the first direction X, such that the first pixel unit groups 1 and the second pixel unit groups 2 are alternately arranged along the first direction X, wherein each first pixel unit group 1 and the adjacent second pixel unit group 2 are axially symmetrical. The first pixel unit group 1 and the second pixel unit group 2 both include two pixels. In each of the first pixel unit group 1 and the second pixel unit group 2, the two pixels are center-symmetrical.

Optionally, the three light-emitting units of different colors in each of the pixels are all triangle-shaped. Each of the light-emitting units includes two short sides and one long side, and a length of the long side is greater than a length of each short side. In each of the pixels, the two short sides of each light-emitting unit form a vertex, the vertices are close to each other, and the extension lines of the long sides of the light-emitting units form an isosceles triangle. That is to say, a shape of each pixel is an isosceles triangle, so that each of the first pixel unit group 1 and the second pixel unit group 2, formed by two pixels which are center-symmetrical to each other, is rhombus-shaped.

Specifically, the first pixel unit group 1 includes a first pixel 20-1 and a second pixel 20-2. The first pixel 20-1 and the second pixel 20-2 are center-symmetrical to each other. The first pixel 20-1 and the second pixel 20-2 are both in a shape of isosceles triangle. The second pixel unit group 2 includes a third pixel 20-3 and a fourth pixel 20-4. The third pixel 20-3 and the fourth pixel 20-4 are center-symmetrical to each other. The pixel 20-3 and the fourth pixel 20-4 are both in a shape of isosceles triangle The first pixel unit group 1 and the adjacent second pixel unit group 2 are axially symmetrical, and therefore, for the first pixel unit group 1 and the adjacent second pixel unit group 2, the first pixel 20-1 in the first pixel unit group I is axisymmetric with the third pixel 20-3 in the second pixel unit group 2, and the second pixel 20-2 in the first pixel unit group 1 is axisymmetric with the fourth pixel 20-4 in the second pixel unit group 2.

Further, in the second direction Y, both the first pixel unit groups 1 and the second pixel unit groups 2 are arranged in an array pattern. Specifically, along the second direction Y, the first pixel unit group 1 and the second pixel unit group 2 are not adjacent to each other. That is to say, in the second direction Y, the first pixel unit groups I alone are arranged in a row, the second pixel unit groups 2 alone are also arranged in a row, and the first pixel unit group 1 and the second pixel unit group 2 are located in different rows. It should be noted that in the present application, the first direction X can be a vertical direction, the second direction Y can be a horizontal direction, and the first direction X is perpendicular to the second direction Y Certainly, the present application is not limited in this regard, the first direction X can also be a horizontal direction, the second direction Y can also be a vertical direction in the present application, and the first direction X and the second direction Y can also form other included angles.

The first pixel unit groups 1 and the second pixel unit groups 2 are both arranged in an array pattern in the second direction Y, and the first pixel unit group I and the second pixel unit group 2 both have two pixels center-symmetric to each other, so that along the second direction Y, any two adjacent pixels are center-symmetric to each other. Further, in the first direction X, the first pixel unit group 1 and the adjacent second pixel unit group 2 are axially symmetrical, so that the adjacent light-emitting units between any two adjacent pixels have the same color. This way, in printing the light-emitting units by inkjet printing, because the adjacent light-emitting units between the two adjacent pixels have the same color, color mixing between the pixels is prevented even if an inkjet printing device has nozzles with limited accuracy, and there is an error that may cause a printing direction to change and lead to ink injection into the adjacent light-emitting unit.

However, it can be understood that, in the same pixel, the adjacent light-emitting units have different colors, so the pixel still have a risk of color mixing. In order to avoid color mixing between the adjacent light-emitting units in the same pixel, a plurality of shielding layers 50 can be disposed between the adjacent light-emitting units in the same pixel to prevent ink from being injected into a pit of the adjacent light-emitting unit.

Specifically, the barrier layers 50 are disposed on one side of the pixel definition layer 40 away from the substrate 10, and each barrier layer 50 is located between two adjacent light-emitting units of different colors. The barrier layer 50 is made of a hydrophobic material. For example, the hydrophobic material can be formed by processing an organic photoresist material to gather fluoride ions on its surface. By arranging each barrier layer 50 between two adjacent light-emitting units of different colors, a height of the barrier layer between the light-emitting units is increased. Therefore, even if a printing nozzle is deviated, the barrier layer 50 can still block deviated ink droplets, so the ink droplets can eventually flow into the pit of the desired light-emitting unit. The barrier layer 50 is made of the hydrophobic material, and as a result, when more ink droplets are injected into the pit of the light-emitting unit, a surface tension caused by hydrophobicity of the barrier layer 50 can ensure that the ink droplets are still in the pit of the light-emitting unit and avoid overflow.

In one embodiment, please refer to FIG. 1 to FIG. 4 in combination. FIG. 4 is a top view of the display panel according to another embodiment of the present application. Different from the above embodiments, on the display panel 101 of the present embodiment, in the second direction Y, the first pixel unit groups 1 and the second pixel unit groups 2 are alternately arranged. In the first direction X, the first pixel unit groups 1 and the second pixel unit groups 2 are also alternately arranged. Accordingly, each first pixel unit group 1 is adjacent to four second pixel unit groups 2, and each second pixel unit group 2 is also adjacent to four first pixel unit groups 1. Moreover, in the first direction X, each first pixel unit group 1 and the adjacent second pixel unit group 2 are axially symmetrical, and in the second direction Y, each first pixel unit group 1 and the adjacent second pixel unit group 2 are also axially symmetrical. Accordingly, the two adjacent light-emitting units between the two adjacent pixels also have the same color.

Specifically, in the first pixel unit group 1 and the second pixel unit group 2, the three light-emitting units of different colors in each pixel are all triangle-shaped. Each light-emitting unit includes two short sides and one long side, wherein a length of the long side is greater than a length of each short side. In each pixel, the vertices formed by the short sides of the light-emitting units are close to each other, and the extension lines of the long sides of the light-emitting units form a right-angled triangle. That is to say, each of the pixels is a right-angled triangle. This way, the first pixel unit group 1 and the second pixel unit group 2, which are both formed by two center-symmetrical pixels, are both in a shape of quadrangle, such as a rectangle or a square.

In addition, the present embodiment is also different from the above embodiment in that in the same pixel, an area of the first-color light-emitting unit B is larger than an area of the second-color light-emitting unit R, and is larger than an area of the third-color light-emitting unit G. The first-color light-emitting unit B is a blue light-emitting unit. The blue light-emitting material has poorer light-emitting efficiency and a shorter lifespan than light-emitting materials of other color. Therefore, in each pixel, the blue light-emitting unit having the larger area can prolong the lifespan of the display panel 101. For other descriptions, please refer to the above-mentioned embodiments, and a detailed description thereof is omitted herein for brevity.

In one embodiment, please refer to FIG. 1 to FIG. 5 in combination. FIG. 5 is a top view of the display panel according to still another embodiment of the present application. The present embodiment is different from the above-mentioned embodiments in that, in the display panel 102, along the first direction X, the first pixel unit group 1 and the adjacent second pixel unit group 2 are center-symmetrical. In the second direction Y, the first pixel unit groups 1 are arranged in an array pattern. In the second direction Y, the second pixel unit groups 2 are also arranged in an array pattern.

Specifically, each of the first pixel unit groups 1 includes a first pixel 20-1 and a second pixel 20-2, wherein the first pixel 20-1 and the second pixel 20-2 are center-symmetrical to each other. Each of the second pixel unit groups 2 includes a third pixel 20-3 and a fourth pixel 20-4, wherein the third pixel 20-3 and the fourth pixel 20-3 are center-symmetrical to each other. In the first direction X, each first pixel unit group 1 and the adjacent second pixel unit group 2 are also center-symmetrical to each other. In the second direction Y, each first pixel unit group 1 and the adjacent second pixel unit group 2 are also center-symmetrical to each other. The structures of the first pixel unit group 1 and the second pixel unit group 2 are exactly the same, that is, the arrangements of the light-emitting units in the first pixel unit group 1 and the second pixel unit group 2 are exactly the same. Accordingly, the adjacent light-emitting units between two adjacent pixels have the same color, and a manufacturing process can be simplified. For other descriptions, please refer to the above-mentioned embodiments, and a detailed description is omitted herein for brevity.

Based on the same inventive concept, the present application further provides an electronic device, and the electronic device includes the display panel 100 of one of the foregoing embodiments. The electronic device can be an electronic display product such as a mobile phone, a television, a tablet computer, and a wearable display device.

From the above embodiments, it can be known that:

In the display panel and the electronic device of the present application, the display panel includes a substrate and a plurality of first pixel unit groups and a plurality of second pixel unit groups alternately arranged on the substrate along a first direction. The first pixel unit groups and each of the second pixel unit groups both include two pixels which are center-symmetrical to each other. Each of the pixels includes at least three light-emitting units of different colors arranged at intervals. In any two adjacent pixels, one of the light-emitting units of one of the two pixels has the same color as the adjacent light-emitting unit of the other pixel. In the present application, each two adjacent light-emitting units between two adjacent pixels have the same color, so that when the light-emitting unit is printed by inkjet printing, color mixing between the pixels can be prevented, thereby solving a color mixing problem between pixels in conventional OLED devices.

In the above-mentioned embodiments, the description of each embodiment has its own emphasis. For those that are not described in detail in a certain embodiment, reference may be made to the relevant descriptions of other embodiments.

The above describes the present application in details. Specific examples are used in the present disclosure to illustrate working principles and embodiments of the present application. The description of the above embodiments is only for ease of understanding the method and main ideas of the present application. Those of ordinary skill in the art can still make modifications to the technical solutions described in the foregoing embodiments, or equivalently replace some of the technical features. Such modifications or replacements fall within the protection scope of the technical solutions of the embodiments of the present application.

What is claimed is:

1. A display panel, comprising:
a substrate; and
a plurality of first pixel unit groups and a plurality of second pixel unit groups alternately arranged on the substrate along a first direction, wherein each of the first pixel unit groups and each of the second pixel unit groups both include two pixels center-symmetrical to each other, and
wherein each of the pixels includes at least three light-emitting units of different colors arranged at intervals; and in any two adjacent pixels, one of the light-emitting units of one of the two pixels has a same color as the adjacent light-emitting unit of the other pixel.

2. The display panel according to claim 1, wherein in the first direction, each first pixel unit group and the adjacent second pixel unit group are axially symmetrical.

3. The display panel according to claim 2, wherein in a second direction, the first pixel unit groups are arranged in an array pattern, and the second pixel unit groups are also arranged in an array pattern; and the first pixel unit groups and the second pixel unit groups are arranged in different rows.

4. The display panel according to claim 3, wherein in the second direction, two adjacent pixels are center-symmetrical.

5. The display panel according to claim 2, wherein in a second direction, the first pixel unit groups and the second pixel unit groups are alternately arranged.

6. The display panel according to claim 5, wherein in the second direction, each first pixel unit group and the adjacent second pixel unit group are axially symmetrical.

7. The display panel according to claim 1, wherein in the first direction, each first pixel unit group and the adjacent second pixel unit group are center-symmetrical.

8. The display panel according to claim 1, wherein the first pixel unit groups and the second pixel unit groups are all rhombus-shaped; the three light-emitting units of different colors in each pixel are all triangle-shaped; each of the light-emitting units comprises two short sides and one long side; in each light-emitting unit, a length of the long side is greater than a length of each short side; and in each of the pixels, the two short sides of each light-emitting unit form a vertex, the vertices are close to each other, and extension lines of the long sides of the light-emitting units form an isosceles triangle.

9. The display panel according to claim 1, wherein the first pixel unit groups and the second pixel unit groups are all square-shaped, the light-emitting units of three different colors in each of the pixels are all triangle-shaped; each of the light-emitting units includes two short sides and one long side; in each light-emitting unit, a length of the long side is greater than a length of each short side; and in each of the pixels, the two short sides of each light-emitting unit form a vertex, the vertices are close to each other, and extension lines of the long sides of the light-emitting units form a right triangle.

10. The display panel according to claim 1, wherein the three light-emitting units of different colors are a first-color light-emitting unit, a second-color light-emitting unit, and a third-color light-emitting unit; each first-color light-emitting unit is a blue light-emitting unit; and within the same pixel, an area of the first-color light-emitting unit is larger than an area of the second-color light-emitting unit and is larger than an area of the third-color light-emitting unit.

11. The display panel according to claim 1, further comprising:
a plurality of first electrodes arranged in an array on the substrate;
a pixel definition layer, wherein the pixel definition layer covers the substrate and the first electrodes and defines a plurality of pixel openings corresponding to the plurality of first electrodes, each pixel opening exposes the corresponding first electrode, and each of the light-emitting units is disposed in one of the pixel openings; and
a plurality of barrier layers disposed on one side of the pixel definition layer away from the substrate, wherein each barrier layer is disposed between two adjacent ones of the light-emitting units of different colors.

12. The display panel according to claim 11, wherein a material of the barrier layer is a hydrophobic material.

13. An electronic device comprising a display panel, wherein the display panel comprises:
a substrate; and
a plurality of first pixel unit groups and a plurality of second pixel unit groups alternately arranged on the substrate along a first direction, wherein each of the first pixel unit groups and each of the second pixel unit groups both include two pixels center-symmetrical to each other, and
wherein each of the pixels includes at least three light-emitting units of different colors arranged at intervals; in any two adjacent pixels, and one of the light-emitting units of one of the two pixels has a same color as the adjacent light-emitting unit of the other pixel.

14. The electronic device according to claim 13, wherein in the first direction, each first pixel unit group and the adjacent second pixel unit group are axially symmetrical.

15. The electronic device according to claim 14, wherein in a second direction, the first pixel unit groups are arranged in an array, and the second pixel unit groups are also arranged in an array; and the first pixel unit groups and the second pixel unit groups are arranged in different rows.

16. The electronic device according to claim 15, wherein in the second direction, two adjacent pixels are center-symmetrical.

17. The electronic device according to claim 14, wherein in a second direction, the first pixel unit groups and the second pixel unit groups are alternately arranged.

18. The electronic device according to claim 17, wherein in the second direction, each first pixel unit group and the adjacent second pixel unit group are axially symmetrical.

19. The electronic device according to claim 13, wherein in the first direction, each first pixel unit group and the adjacent second pixel unit group are center-symmetrical.

20. The electronic device according to claim 13, wherein the display panel further comprises:
a plurality of first electrodes arranged in an array on the substrate;
a pixel definition layer, wherein the pixel definition layer covers the substrate and the first electrodes and defines a plurality of pixel openings corresponding to the plurality of first electrodes, each pixel opening exposes the corresponding first electrode, and each of the light-emitting units is disposed in one of the pixel openings; and
a plurality of barrier layers disposed on one side of the pixel definition layer away from the substrate, wherein each barrier layer is disposed between two adjacent ones of the light-emitting units of different colors.
